(19) United States
(12) Patent Application Publication
(10) Pub. No.: US 2020/0044136 A1
(43) Pub. Date: Feb. 6, 2020

(54) MANUFACTURING METHOD OF THERMOELECTRIC CONVERSION DEVICE HAVING TEXTILE STRUCTURE

(71) Applicant: DONGHUAJNGYUE (SUZHOU) TEXTILE TECHNOLOGY RESEARCH CO., LTD, Suzhou (CN)

(72) Inventors: Kun ZHANG, Suzhou (CN); Yuanyuan ZHENG, Suzhou (CN)

(21) Appl. No.: 16/481,635

(22) PCT Filed: Jan. 22, 2018
(86) PCT No.: PCT/CN2018/073627

§ 371 Date: Jul. 29, 2019

(30) Foreign Application Priority Data
Oct. 30, 2017 (CN) 201711035633.6

(51) Int. Cl. H01L 35/34; D03D 15/00; D03D 25/00; D04B 21/00; D04B 1/14; D04C 1/02; H01L 35/32; G01K 7/02

(52) U.S. Cl. CPC H01L 35/34; D03D 15/00; D03D 25/005; D04B 21/00; D10B 2401/16; D04C 1/02; H01L 35/32; G01K 7/02; D04B 1/14

(57) ABSTRACT

A manufacturing method of a thermoelectric conversion device having a textile structure. The thermoelectric conversion device having a textile structure uses one or multiple types of thermoelectric yarns as thermocouples of a thermoelectric generator structure, and uses elastic insulating yarns as a main carrier portion of a textile article. The invention utilizes the characteristic of a textile article of having woven and overlapping warp and weft yarns, and the thermoelectric yarns are woven into a thermoelectric generator textile article by using a conventional weaving technique. The thermoelectric transfer performance and the performance of the main carrier thereof are adjusted by varying an interweaving structure of the textile article, placement positions of the thermoelectric yarns, and the length of the thermocouples thereof. The present invention is widely and flexibly applicable in the fields of sports and health, medical smart apparel, smart homes, wearable touch screens, electronics, even automobiles, architectures, and the like.

### TECHNICAL FIELD

The disclosure relates to the field of thermoelectric generation, and more particularly to an N-type, P-type, and PN-type thermoelectric yarn, a thermoelectric fabric, and corresponding manufacturing methods.

### BACKGROUND

Thermoelectric fabric is a green energy material that can directly convert heat energy into electricity, and its performance mainly depends on the thermoelectric figure of merit. The thermoelectric fabric with high thermoelectric figure of merit has high thermoelectric conversion efficiency. The thermoelectric fabric has attracted wide attention because of its environmental friendliness, non-pollution, process easiness, and energy conversion without media involvement.

Textiles have close contact with human body and can be used as excellent flexible carriers for various micro and nano electronic devices. The thermoelectric devices of fabrics by combining fabrics with thermoelectric devices can provide energy for micro- and nano-electronic devices. The three-dimensional textile structure can be one-step formed and exhibits excellent mechanical properties. It has been applied in some fields. For example, combining the three-dimensional textile structure with thermoelectricity to develop high-performance thermoelectric devices, which can be used in building structures, automobiles and other fields. Chinese Patent Publication No. CN101056481B discloses a textile structure including a thermoelectric structure formed by wires, dielectric wires, sewing threads and the like using jacquard knitting method. Chinese Patent Publication No. CN106206923A discloses a flexible wearable thermoelectric generating device, which is a layered power generation fabric including an upper substrate, a lower substrate, a copper foil, an upper textile layer, a lower textile layer, a thermal insulation layer, P-type semiconductor particles, N-type semiconductor particles, and a flexible conductor. Chinese Patent Publication No. CN106415865A discloses a three-dimensional orthogonal thermoelectric fabric which comprises a closed loop formed by two different metal wires and elastic filaments covering the closed loop. Chinese Patent Publication No. CN10313865A teaches a thermoelectric textile and its manufacturing method. The thermoelectric textile is formed by a base cloth and at least two thermoelectric conductive wires of different materials interlaced on the base cloth by sewing or embroidery.

The above existing thermoelectric fabrics involve a wide range of raw materials, have complex structure, inefficient manufacturing process, single variety, uneven structure control. This results in the low thermoelectric conversion efficiency of the textile structural materials, and the temperature difference and current direction of most thermoelectric fabrics are in-plane direction, so it is impossible to use the temperature difference along the thickness direction of the fabric to produce current, thus limiting the application of such textile thermoelectric fabrics.

### SUMMARY

Disclosed is a method of manufacturing a thermoelectric conversion device having textile structure using thermoelectric yarn. The design and weaving method of the thermoelectric structure fabrics has low cost and high efficiency, overcomes the shortcomings of conventional processes such as various raw materials, complex structure, and difficult manufacturing process, as well as the defects of single variety, uneven structure, low thermoelectric conversion efficiency of conventional textile structure materials. The generated current is along the thickness direction of the fabric, so the thermoelectric fabric has broad application prospects.

To achieve the above objective, the following technical solutions are adopted.

A method of manufacturing a thermoelectric conversion device having textile structure comprises preparation of thermoelectric yarns and design and preparation of thermoelectric fabrics with thermoelectric power generation function. Spherically, first, preparing an N-type, P-type, and PN-type thermoelectric yarn using a direct method, an indirect method, or a combination thereof and second, weaving the thermoelectric yarn with certain elasticity and weavability, to yield a thermoelectric fabric with thermoelectric power generation function. The thermoelectric fabric has the functions of thermoelectric power generation and electric refrigeration.

The thermoelectric yarn is a core-spun yarn structure or homogeneous structure along a yarn diameter direction. The thermoelectric yarn comprises a conductive component which employs an inorganic thermoelectric fabric, an organic thermoelectric fabric, or a mixture thereof. The thermoelectric yarn is prepared by a direct method, doping, coating, in-situ polymerization, or a combination thereof. The conductive type of the thermoelectric yarn is adjusted by adjusting a type of the thermoelectric fabric. The power generation efficiency of the thermoelectric yarn is regulated by adjusting PN junction length and fabric density.

The thermoelectric fabric is made by weaving, knitting, crocheting, or a combination thereof. The thermoelectric fabric with thermoelectric power generation function is a two-dimensional or three-dimensional textile structure.

Advantages of the method of manufacturing a thermoelectric conversion device having textile structure as described in the disclosure are summarized as follows. The thermoelectric conversion device having textile structure employs one or more thermoelectric yarns as thermocouples, and elastic insulated yarns as a main load-bearing part of fabric. Utilizing the overlapping characteristics of warp and weft yarns of fabrics, the thermoelectric yarns are woven by traditional textile technology to form thermoelectric fabric structure. By changing the interlacing structure of fabrics, the placement position of thermoelectric yarns and the length of the thermal couples, the thermoelectric transmission performance and the main load-carrying capacity of the fabric are changed. The thermoelectric fabric structure can be widely and flexibly used in sports health and medical smart clothing, smart home, wearing touch screens, electronics, even automobiles, construction and other fields. The design and weaving method of the thermoelectric structure fabrics has low cost and high efficiency, overcomes the shortcomings of conventional processes such as various raw materials, complex structure, and difficult manufacturing process, as well as the defects of single variety, uneven structure, low thermoelectric conversion efficiency of conventional textile structure materials. The generated current is along the thickness direction of the fabric, so the thermoelectric fabric has broad application prospects.

### BRIEF DESCRIPTION OF THE DRAWINGS

FIG. 1 is an equivalent circuit diagram of thermoelectric power generation of a thermoelectric fabric.

FIG. 2 is a cyclic weaving diagram of a plain thermoelectric fabric.

FIG. 3 is a cyclic weaving diagram of a weft knitting thermoelectric fabric.

FIG. 4 is a cyclic weaving diagram of a three-directional orthogonal thermoelectric fabric.

FIG. 5 is a cyclic weaving diagram of a sutured thermoelectric fabric.

FIG. 6 is a cyclic weaving diagram of a spacer thermoelectric fabric.

### DETAILED DESCRIPTION

To further illustrate, embodiments detailing a method of manufacturing a thermoelectric conversion device having textile structure are described below. It should be noted that the following embodiments are intended to describe and not to limit the disclosure.

A method of manufacturing a thermoelectric conversion device having textile structure comprises preparing an N-type, P-type, and PN-type thermoelectric yarn using a direct method, an indirect method such as doping, coating, spraying, in-situ polymerization, or a combination thereof; and weaving the thermoelectric yarn with certain elasticity and weavability, to yield a thermoelectric fabric with thermoelectric power generation function. The thermoelectric fabric has the functions of thermoelectric power generation and electric refrigeration.

### Example 1

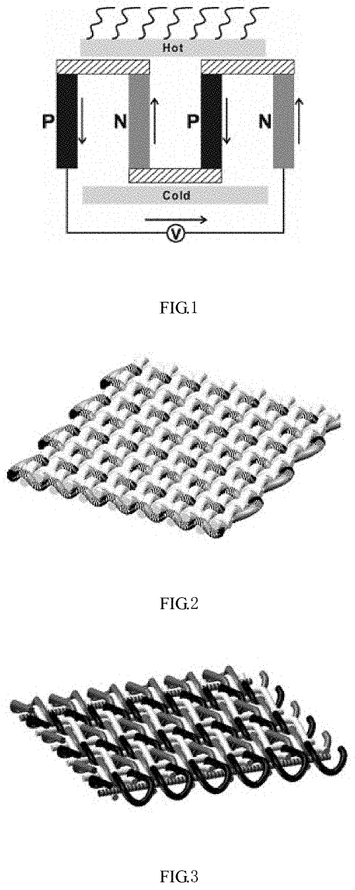

As shown in FIG. 2, the thermoelectric fabric of this example is a plain weave structure. The insulated warp yarn is arranged on a sample weaving machine along the direction of fabric forming. A PN type thermoelectric yarn and an insulated yarn are introduced alternately as weft yarns. After several cycles, the required fabric is formed. As shown in FIG. 2, a constant current is generated when the temperature difference is applied in the direction of fabric thickness.

In this example, the weaving machine used therein includes but is not limited to a sample weaving machine; and the yarns used are soft, strong and weavable.

### Example 2

As shown in FIG. 3, the thermoelectric fabric of this example is a weft knitting structure. The P type thermoelectric yarn, N type thermoelectric yarn, insulated yarn and thermoelectric yarn are employed. The P-type thermoelectric yarn and N-type thermoelectric yarn are fed alternately into the crochet of a knitting machine to form the required fabric after several cycles, followed by introduction of the insulation yarn and thermoelectric yarn. A constant current is generated when the temperature difference is applied in the direction of fabric thickness.

In this example, the weaving machine used therein includes but is not limited to a knitting machine; and the yarns used are soft, strong and weavable. On the one hand, the insulated yarns bear the transition of partial temperature difference. More importantly, they can avoid the short circuit in the fabric. The priority and the introduction mode of the insulated yarn and thermoelectric yarn are not limited by the example.

### Example 3

As shown in FIG. 4, the thermoelectric fabric of this example is a three-directional orthogonal woven structure. FIG. 4 shows the yarns used in the example. The insulated warp yarns are arranged on a three-dimensional weaving machine in a certain warp density along the direction of fabric forming, and a PN-type thermoelectric yarn and an insulated weft yarn are introduced sequentially. The number of weaving cycles is controlled according to the length of the required fabric, so that the required fabric can be obtained. A constant current is generated when the temperature difference is applied in the direction of fabric thickness.

In this example, the weaving machine used therein includes but is not limited to a three-dimensional weaving machine; and the yarns used are soft, strong and weavable. The number of layers of insulated warp yarns should be determined according to the required fabric thickness; the insulated warp yarn and insulated weft yarn constitute the fabric thickness and bear the transition of temperature difference, and insulated warp yarn will also separate the PN-type thermoelectric yarns, so as to avoid short circuit in the fabric.

### Example 4

As shown in FIG. 5, the thermoelectric fabric of this example is a sutured structure. The insulation fabrics are overlapped in order, and PN-type yarns are sewn into the fabrics. The PN-type yarns are arranged according to the number and position of required thermocouples, to yield a complete generating fabric. A constant current is generated when the temperature difference is applied in the direction of fabric thickness.

In this example, the suture methods are automatic, semi-automatic and/or non-automatic, and the suture methods include but are not limited to a locking suture. The yarns used are soft, strong and weavable. The fabric types are unlimited, and the upper and lower layers are the same or different; fabric dimensions are unlimited, including two-dimensional and three-dimensional fabrics, and the thickness of each two-dimensional and three-dimensional fabric is unlimited; overlapped insulated fabrics are unlimited, but should be greater than or equal to one layer. The insulated fabrics play the role of bearing temperature difference transition, and separate PN-type thermoelectric yarns to avoid short circuit.

### Example 5

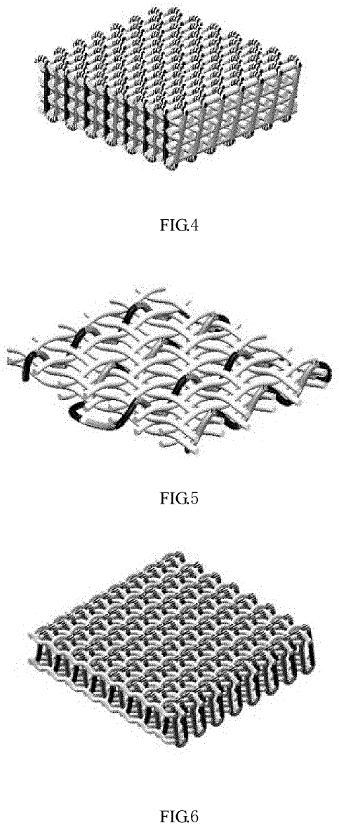

As shown in FIG. 6, the thermoelectric fabric of this example is a spacer fabric structure comprising three systemic yarn layers, that is, two surface yarn layers and one spacer yarn layer. The two surface yarn layers are composed of insulated yarns, and the spacer yarn layer is composed of PN-type thermoelectric yarns. The upper and lower yarn layers are arranged according to the preset interval, and a PN-type yarn is used to connect the two layers of the fabric. The arrangement of the PN-type yarn is arranged according to the number and position of required thermocouples, to form a complete power-generating fabric. A constant current is generated when the temperature difference is applied in the direction of fabric thickness.

In this example, the fabric forming method includes but is not limited to a manual mode. The yarns used are soft, strong and weavable. The connection mode of the PN-type thermoelectric yarns is not limited to the mode taught in this example. The connection mode can be changed to ensure the formation of a whole fabric. The types of the two surface yarn layers are the same or different. The upper and lower layers of fabric organization is not limited. The upper and lower surface layers play the role of bearing the transition of the temperature difference.

It will be obvious to those skilled in the art that changes and modifications may be made, and therefore, the aim in the appended claims is to cover all such changes and modifications.

What is claimed is:

1. A method of manufacturing a thermoelectric conversion device having textile structure, comprising:
1) preparing an N-type, P-type, and PN-type thermoelectric yarn using a direct method, an indirect method, or a combination thereof; and
2) weaving the thermoelectric yarn with certain elasticity and weavability, to yield a thermoelectric fabric with thermoelectric power generation function.

2. The method of claim 1, wherein the thermoelectric yarn comprises a conductive component which employs an inorganic thermoelectric fabric, an organic thermoelectric fabric, or a mixture thereof.

3. The method of claim 1, wherein the thermoelectric yarn is a core-spun yarn structure or homogeneous structure along a yarn diameter direction.

4. The method of claim 1, wherein the thermoelectric yarn comprises a conductive component which employs an inorganic thermoelectric fabric, an organic thermoelectric fabric, or a mixture thereof.

5. The method of claim 1, wherein the thermoelectric yarn is prepared by a direct method, doping, coating, in-situ polymerization, or a combination thereof.

6. The method of claim 1, wherein a conductive type of the thermoelectric yarn is adjusted by adjusting a type of the thermoelectric fabric.

7. The method of claim 1, wherein a power generation efficiency of the thermoelectric yarn is regulated by adjusting PN junction length and fabric density.

8. The method of claim 1, wherein the thermoelectric fabric is made by weaving, knitting, crocheting, or a combination thereof.

9. The method of claim 1, wherein the thermoelectric fabric with thermoelectric power generation function is a two-dimensional or three-dimensional textile structure.
